(19) United States
(12) Patent Application Publication
(10) Pub. No.: US 2016/0111477 A1
(43) Pub. Date: Apr. 21, 2016

(54) PIXEL CIRCUIT OF DISPLAY AND COMPENSATION METHOD THEREOF

(71) Applicant: EverDisplay Optronics (Shanghai) Limited, Shanghai City (CN)

(72) Inventor: Geiyoung HO, Shanghai City (CN)

(21) Appl. No.: 14/682,994

(22) Filed: Apr. 9, 2015

(30) Foreign Application Priority Data
Oct. 15, 2014 (CN) 201410545535.7

(51) Int. Cl. H01L 27/32

(52) U.S. Cl. CPC H01L 27/3223; H01L 27/3276; H01L 27/3262; H01L 27/3265; H01L 27/3248

(57) ABSTRACT

The present disclosure provides a pixel circuit of a display and a compensation method thereof. The pixel circuit includes: a plurality of gate lines; a plurality of data lines intersecting with and being insulated against the plurality of gate lines; a plurality of common power lines intersecting with and being insulated against the plurality of gate lines; a plurality of pixel units defined in regions encircled by the plurality of gate lines, the plurality of data lines, and the plurality of common power lines; and a dummy gate line, extended in the same direction as the plurality of gate lines, intersecting with and being insulated against the plurality of data lines and the plurality of common power lines, wherein an offset common potential obtained on the dummy gate line is configured to make a common potential compensation for the pixel circuit.

### CROSS REFERENCE TO RELATED APPLICATIONS

This application is based upon and claims priority to Chinese Patent Application No. 201410545535.7, filed on Oct. 15, 2014, the entire contents of which are incorporated herein by reference.

### TECHNICAL FIELD

The present disclosure relates to a pixel circuit of a display, and in particular, relates to a pixel circuit of a display and a compensation method thereof.

### BACKGROUND

Organic light-emitting displays have the feature of self-emitting light, and employ very thin organic material coatings and glass substrates. When a current flows through, the organic materials emit light. In addition, view angles of screens of the organic light-emitting displays are large, and electric energy may be notably saved with such displays. Therefore, the organic light-emitting displays possess incomparable advantages over most liquid crystal displays.

Organic light-emitting displays may be categorized into a passive matrix type and an active matrix type. In the passive matrix type of organic light-emitting displays, pixels are arranged in the form of matrix at the intersection sites of scanning lines and signal lines. In the active matrix type of organic light-emitting displays, pixels are controlled by thin-film transistors which are operable like switches.

FIG. 1 is a circuit diagram of a pixel circuit of a traditional organic light-emitting display.

Referring to FIG. 1, the pixel circuit of the traditional organic light-emitting display includes: a plurality of gate lines G1 to Gn extending in the same direction, a plurality of data lines S1 to Sm extending in the same direction, a plurality of common power lines D1 to Dm extending in the same direction, and a plurality of pixel units 101. The number of data lines is the same as the number of common power lines. The plurality of data lines S1 to Sm intersect with and are insulated against the plurality of gate lines G1 to Gn. The plurality of common power lines D1 to Dm intersect with and are insulated against the plurality of gate lines G1 to Gn. The plurality of pixel units 101 are each defined in regions encircled by the plurality of gate lines, the plurality of data lines, and the plurality of common power lines.

FIG. 2 is a circuit diagram of the pixel unit 101. Each of the plurality of pixel units 101 includes: a switch thin-film transistor 108, a drive thin-film transistor 112, a capacitor 110, and an organic light-emitting diode 114. Each of the plurality of pixel units 101 is defined in a region encircled by gate lines 102, a data line 104, and a common power line 106.

The organic light-emitting diode 114 includes a pixel electrode, an organic emitting layer formed on the pixel electrode, and a common electrode formed on the organic emitting layer. The pixel electrode serves as an anode of a hole injection electrode, and the common electrode serves as a cathode of an electron injection electrode. In a varied embodiment, according to a drive method of an organic light-emitting display, the pixel electrode may serve as the cathode, and the common electrode may serve as the anode. The hole and the electron are respectively injected into the organic emitting layer from the pixel electrode and the common electrode, and thus an exciton is formed. When the exciton transits from an excitation state to a ground state, light is emitted.

The switch thin-film transistor 108 includes: a switch semiconductor layer (not illustrated in the drawing), a switch gate electrode 107, a switch source electrode 103, and a switch drain electrode 105. The drive thin-film transistor 112 includes: a drive semiconductor layer (not illustrated in the drawing), a drive gate electrode 115, a drive source electrode 113, and a drive drain electrode 117.

The capacitor 110 includes a first sustain electrode 109 and a second sustain electrode 111, wherein an interlayer insulating layer is disposed between the first sustain electrode 109 and the second sustain electrode 111.

The switch thin-film transistor 108 serves as a switch for selecting a pixel for light emitting. The switch gate electrode 107 is connected to the gate line 102. The switch source electrode 103 is connected to the data line 104. The switch drain electrode 105 is disposed as being spaced apart from the switch source electrode 103 by a specific distance, and the switch drain electrode 105 is connected to the first sustain electrode 109.

The drive thin-film transistor 112 applies a drive power to the pixel electrode, such that the organic emitting layer of the organic light-emitting diode 114 of the selected pixel emits light. The drive gate electrode 115 is connected to the first sustain electrode. The drive source electrode 113 and the second sustain electrode 111 are each connected to the common power line 106. The drive drain electrode 117 is connected via a contact hole to the pixel electrode of the organic light-emitting diode 114.

With the above structure, the switch thin-film transistor 108 is driven by a gate voltage applied to the gate lines 102, such that a data voltage applied to the data line 104 is transferred to the drive thin-film transistor 112. A voltage corresponding to the voltage difference between the common voltage transferred from the common power line 106 to the drive thin-film transistor 112 and the data voltage transferred via the switch thin-film transistor 108 is stored in the capacitor 110, and a current corresponding to the voltage stored in the capacitor 110 flows through the drive thin-film transistor 112 to the organic light-emitting diode 114. In this way, the organic light-emitting diode 114 emits light.

Further, the voltage source of the organic light-emitting display is a major factor affecting the brightness thereof. Therefore, stability of the voltage source is an important indicator affecting the property of the organic light-emitting display.

High resolution organic light-emitting displays would inevitably prevail in the market. However, high resolution panels cause short charging time, and an increase of the number of data lines. These two factors may both cause disturbances to the voltage source of the organic light-emitting display, such that the originally stable potential fails to be restored.

Specifically, FIG. 3 is a schematic diagram illustrating common potential changes of a traditional low resolution organic light-emitting display. The charging time of the traditional low resolution organic light-emitting display is relatively long. Therefore, after being subject to disturbances, the traditional low resolution organic light-emitting display has sufficient time to return to a reference common potential, and then normally supplies power such that the organic light-emitting display is capable of emitting light normally.

However, with respect to a high resolution organic light-emitting display, the number of data lines is increased and the charging time is reduced, such that the common potential subject to disturbances fails to restore to the reference common potential within the charging time. FIG. 4 is a schematic diagram illustrating common potential changes of a high resolution organic light-emitting display. Under such circumstances, the brightness of the organic light-emitting display is affected.

### SUMMARY

One aspect of the present disclosure provides a pixel circuit of a display, including: a plurality of gate lines; a plurality of data lines intersecting with and being insulated against the plurality of gate lines; a plurality of common power lines intersecting with and being insulated against the plurality of gate lines; a plurality of pixel units defined in regions encircled by the plurality of gate lines, the plurality of data lines, and the plurality of common power lines; and a dummy gate line, extended in the same direction as the plurality of gate lines, intersecting with and being insulated against the plurality of data lines and the plurality of common power lines, wherein an offset common potential obtained on the dummy gate line is configured to make a common potential compensation for the pixel circuit.

Optionally, the dummy gate line is positioned on one side of the plurality of gate lines.

Optionally, the pixel circuit further includes: a plurality of dummy pixel units defined in regions encircled by the dummy gate line, the plurality of data lines, and the plurality of common power lines.

Optionally, the plurality of dummy pixel units have the same circuit structure as each of the plurality of pixel units.

Optionally, each of the plurality of pixel units includes: a switch thin-film transistor, having a switch gate electrode, a switch source electrode, and a switch drain electrode; a drive thin-film transistor, having a drive gate electrode, a drive source electrode, and a drive drain electrode; a capacitor, having a first sustain electrode and a second sustain electrode; and a light-emitting diode; wherein the switch gate electrode of the switch thin-film transistor is connected to the gate line, the switch source electrode of the switch thin-film transistor is connected to the data line, the switch drain electrode of the switch thin-film transistor is connected to the first sustain electrode and the drive gate electrode of the drive thin-film transistor, the drive source electrode of the drive thin-film transistor and the second sustain electrode of the capacitor are respectively connected to the common power line, the drive drain electrode of the drive thin-film transistor is connected to a positive pole of the light-emitting diode, and a negative pole of the light-emitting diode is grounded.

Optionally, the switch thin-film transistor and the drive thin-film transistor employ one of the following structures: a p-channel metal oxide semiconductor (PMOS) structure; an n-channel metal oxide semiconductor (NMOS) structure; and a complementary metal oxide semiconductor (CMOS) structure.

Optionally, the switch thin-film transistor and the drive thin-film transistor employ one of the following transistors: a polysilicon thin-film transistor; and an amorphous silicon thin-film transistor.

Optionally, the capacitor is a ceramic capacitor.

Optionally, the light-emitting diode is an organic light-emitting diode.

Optionally, each of the plurality of pixel units includes: a switch thin-film transistor, having a switch gate electrode, a switch source electrode, and a switch drain electrode; a drive thin-film transistor, having a drive gate electrode, a drive source electrode, and a drive drain electrode; a capacitor, having a first sustain electrode and a second sustain electrode; and a light-emitting diode; wherein the switch gate electrode of the switch thin-film transistor is connected to the gate line, the switch source electrode of the switch thin-film transistor is connected to the data line, the switch drain electrode of the switch thin-film transistor is connected to the first sustain electrode and the drive gate electrode of the drive thin-film transistor, the drive drain electrode of the drive thin-film transistor and the second sustain electrode of the capacitor are respectively grounded, the drive source electrode of the drive thin-film transistor is connected to a negative pole of the light-emitting diode, and a positive pole of the light-emitting diode is connected to the common power line.

Optionally, the switch thin-film transistor and the drive thin-film transistor employ one of the following structures: a PMOS structure; an NMOS structure; and a CMOS structure.

Optionally, the switch thin-film transistor and the drive thin-film transistor employ one of the following transistors: a polysilicon thin-film transistor; and an amorphous silicon thin-film transistor.

Optionally, the capacitor is a ceramic capacitor.

Optionally, the light-emitting diode is an organic light-emitting diode.

Optionally, each of the plurality of pixel units includes: a first switch thin-film transistor, having a first switch gate electrode, a first switch source electrode, and a first switch drain electrode; a second switch thin-film transistor, having a second switch gate electrode, a second switch source electrode, and a second switch drain electrode; a drive thin-film transistor, having a drive gate electrode, a drive source electrode, and a drive drain electrode; a capacitor, having a first sustain electrode and a second sustain electrode; and a light-emitting diode; wherein the first switch gate electrode of the first switch thin-film transistor is connected to a first gate line, the first switch source electrode of the first switch thin-film transistor is connected to the data line, the first switch drain electrode of the first switch thin-film transistor is connected to the first sustain electrode of the capacitor and the drive gate electrode of the drive thin-film transistor, the drive source electrode of the drive thin-film transistor and the second sustain electrode are respectively connected to the common power line, the drive drain electrode of the drive thin-film transistor is connected to the second switch source electrode of the second switch thin-film transistor, the second switch gate electrode of the second switch thin-film transistor is connected to a second gate line, the second switch drain electrode of the second switch thin-film transistor is connected to a positive pole of the light-emitting diode, and a negative pole of the light-emitting diode is grounded.

Optionally, an input level of the first gate line is reverse to that of the second gate line.

Optionally, the first switch thin-film transistor, the second switch thin-film transistor, and the drive thin-film transistor employ one of the following structures: a PMOS structure; an NMOS structure; and a CMOS structure.

Optionally, the first switch thin-film transistor, the second switch thin-film transistor, and the drive thin-film transistor employ one of the following transistors: a polysilicon thin-film transistor; and an amorphous silicon thin-film transistor.

Optionally, the capacitor is a ceramic capacitor.

Optionally, the light-emitting diode is an organic light-emitting diode.

Another aspect of the present disclosure provides a common potential compensation method based on the above-described pixel circuit, including: obtaining a reference common potential; obtaining an offset common potential on the dummy gate line; and reversing the offset common potential and raising the reversed offset common potential to the reference common potential.

According to the present disclosure, a dummy gate line is added in a pixel circuit of an organic light-emitting display, such that dummy pixel units are added accordingly, wherein the dummy pixel units are the same as the pixel units in terms of structure. An offset common potential may be obtained in real time on the dummy gate line. The offset common potential is reversed and then raised to the reference common potential, such that the organic light-emitting display is capable of emitting light normally.

### BRIEF DESCRIPTION OF THE DRAWINGS

Exemplary embodiments of the present disclosure will be described in detail with reference to the accompanying drawings, so that the above and other features and advantages of the present invention would become more obvious.

FIG. 1 is a schematic circuit diagram of a pixel circuit of an organic light-emitting display according to the related art;

FIG. 2 is a schematic circuit diagram of a pixel unit of the pixel circuit of an organic light-emitting display according to the related art;

FIG. 3 is a schematic diagram illustrating common potential changes of a low resolution organic light-emitting display according to the related art;

FIG. 4 is a schematic diagram illustrating common potential changes of a high resolution organic light-emitting display according to the related art;

FIG. 5 is a schematic circuit diagram of a pixel circuit of an organic light-emitting display according to the present disclosure;

FIG. 6 is a schematic circuit diagram of a pixel unit of the pixel circuit of an organic light-emitting display according to a first embodiment of the present disclosure;

FIG. 7 is a schematic circuit diagram of a pixel unit of the pixel circuit of an organic light-emitting display according to a second embodiment of the present disclosure;

FIG. 8 is a schematic circuit diagram of a pixel unit of the pixel circuit of an organic light-emitting display according to a third embodiment of the present disclosure;

FIG. 9 is a flowchart of a compensation method of a pixel circuit of an organic light-emitting display according to the present disclosure; and

FIG. 10 is a schematic diagram illustrating common potential changes of the pixel circuit of an organic light-emitting display according to the present disclosure.

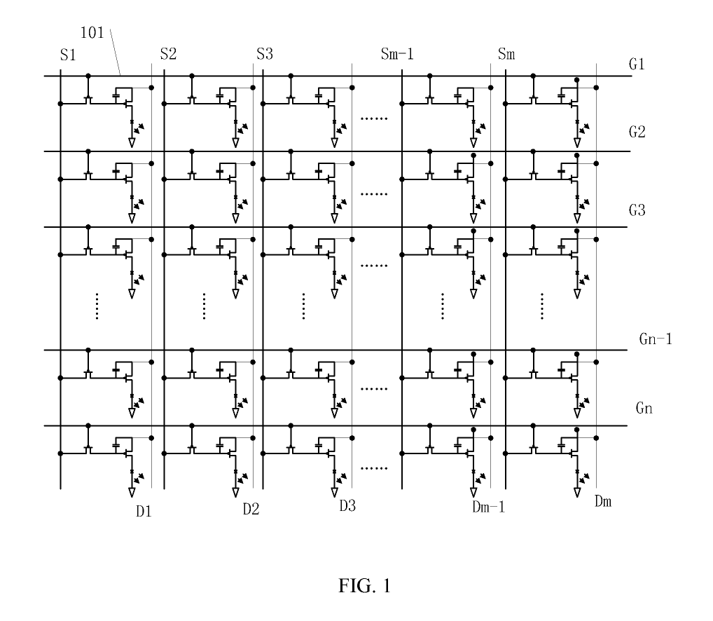

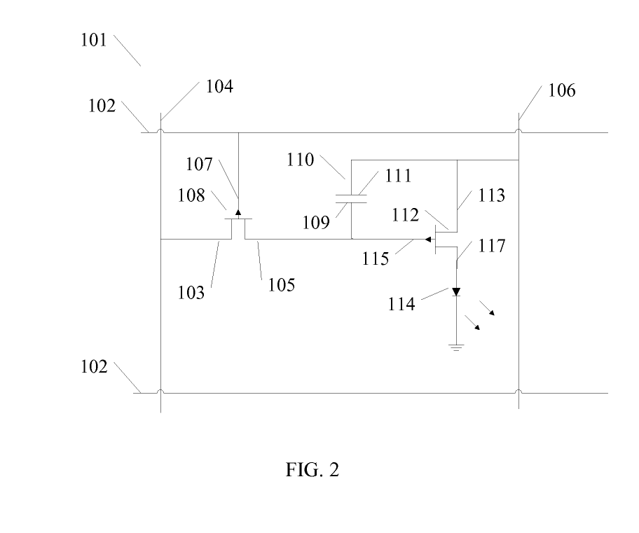

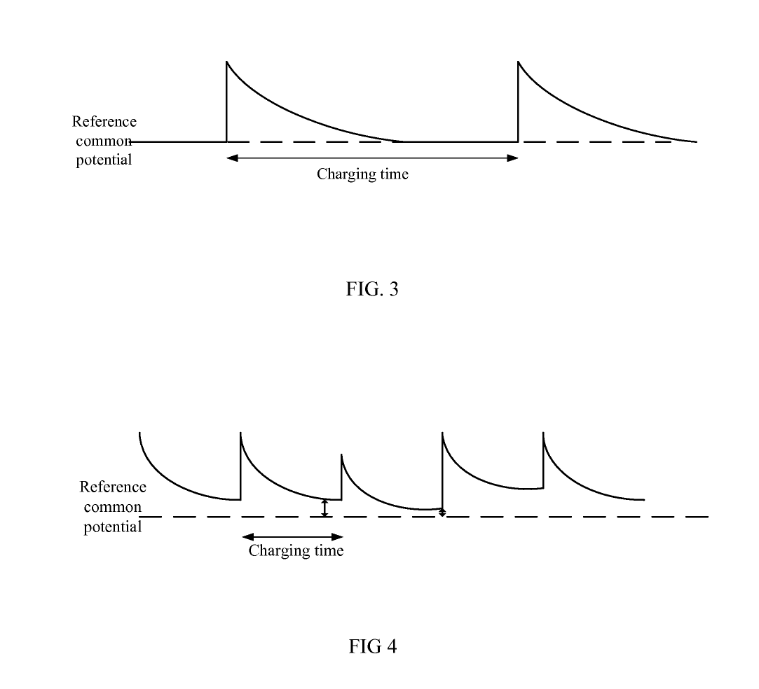

### DETAILED DESCRIPTION

Exemplary embodiments of the present disclosure are hereinafter described in detail with reference to accompany drawings. However, the exemplary embodiments may be implemented in a plurality of manners, and shall not be construed as being limited to the implementation described hereinafter. On the contrary, such exemplary embodiments more thoroughly and completely illustrate the present disclosure, and fully convey the concepts of the exemplary embodiments to persons skilled in the art. In the drawings, for clear description, the thicknesses of the regions and layers are enlarged. In the drawings, like reference numerals denote like or similar structures or elements. Therefore, detailed descriptions of these structures or elements are not given any further.

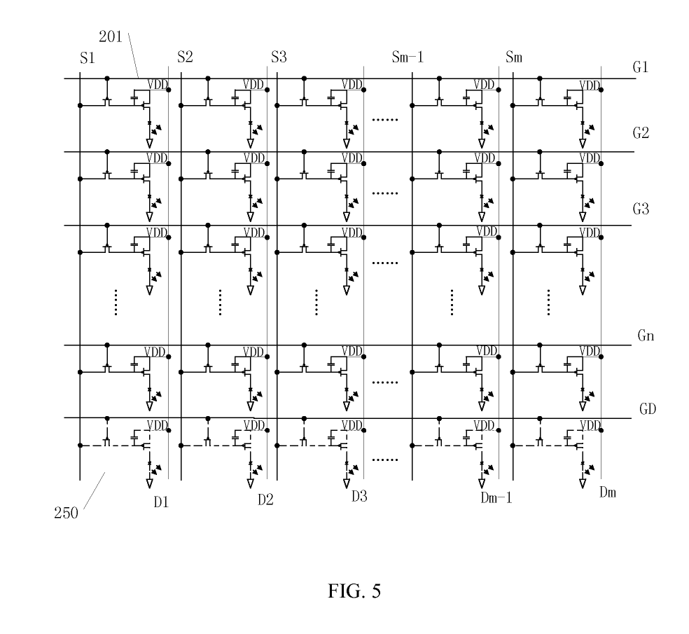

FIG. 5 is a schematic circuit diagram of a pixel circuit of an organic light-emitting display according to the present disclosure. The pixel circuit of the organic light-emitting display includes: a plurality of gate lines G1 to Gn extending in the same direction, a plurality of data lines S1 to Sm extending in the same direction, a plurality of common power lines D1 to Dm extending in the same direction, a plurality of pixel units 201, a dummy gate line GD, and a plurality of dummy pixel units 250. An offset common potential obtained on the dummy gate line GD is used to make a common potential compensation for the pixel circuit.

The number of data lines is the same as the number of common power lines. The plurality of data lines S1 to Sm intersect with and are insulated against the plurality of gate lines G1 to Gn. The plurality of common power lines D1 to Dm (potential VDD) intersect with and are insulated against the plurality of gate lines G1 to Gn. Each of the plurality of pixel units 201 is defined in a region encircled by the gate lines, the data line, and the common power line. The dummy gate line GD intersects with and is insulated against the plurality of data lines S1 to Sm and the plurality of common power lines D1 to Dm. Optionally, the dummy gate line GD is positioned on one side of the plurality of gate lines, for example, on a lower side of the gate line Gn (as illustrated in FIG. 5). Each of the plurality of dummy pixel units 250 is defined in a region encircled by the dummy gate line GD, the data line, and the common power line. The dummy pixel unit 250 has the same circuit structure as the pixel unit 201. Each of the plurality of pixel units 201 includes: one or a plurality of thin-film transistors, one or a plurality of capacitors, and one light-emitting diode. Whereas each of the plurality of dummy pixel units 250, in another exemplary embodiment, includes no thin-film transistor, no capacitor, or no light-emitting diode.

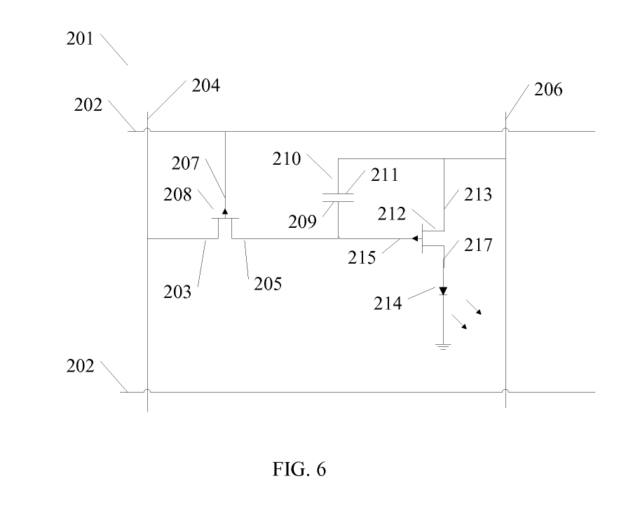

FIG. 6 is a schematic circuit diagram of a pixel unit of the pixel circuit of an organic light-emitting display according to a first embodiment of the present disclosure. Each of the plurality of pixel units 201 includes: a switch thin-film transistor 208, a drive thin-film transistor 212, a capacitor 210, and an organic light-emitting diode 214. Each of the plurality of pixel units 201 is defined in a region encircled by gate lines 202, a data line 204, and a common power line 206.

The organic light-emitting diode 214 includes a pixel electrode, an organic emitting layer formed on the pixel electrode, and a common electrode formed on the organic emitting layer. The pixel electrode serves as an anode of a hole injection electrode, and the common electrode serves as a cathode of an electron injection electrode. In a varied embodiment, according to a drive method of an organic light-emitting display, the pixel electrode may serve as the cathode, and the common electrode may serve as the anode. The hole and the electron are respectively injected into an organic emitting layer from the pixel electrode and the common electrode, and thus an exciton is formed. When the exciton transits from an excitation state to a ground state, light is emitted.

The switch thin-film transistor 208 includes: a switch semiconductor layer (not illustrated in the drawing), a switch gate electrode 207, a switch source electrode 203, and a switch drain electrode 205. The drive thin-film transistor 212 includes: a drive semiconductor layer (not illustrated in the drawing), a drive gate electrode 215, a drive source electrode 213, and a drive drain electrode 217.

The capacitor 210 includes a first sustain electrode 209 and a second sustain electrode 211, wherein an interlayer insulating layer is disposed between the first sustain electrode 209 and the second sustain electrode 211.

The switch thin-film transistor 208 serves as a switch for selecting a pixel for light emitting. The switch gate electrode 207 is connected to the gate line 202. The switch source electrode 203 is connected to the data line 204. The switch drain electrode 205 is disposed as being spaced apart from the switch source electrode 203 by a specific distance, and the switch drain electrode 205 is connected to the first sustain electrode 209.

The drive thin-film transistor 212 applies a drive power to the pixel electrode, such that the organic emitting layer of the organic light-emitting diode 214 of the selected pixel emits light. The drive gate electrode 215 is connected to the first sustain electrode. The drive source electrode 213 and the second sustain electrode 211 are each connected to the common power line 206. The drive drain electrode 217 is connected via a contact hole to the pixel electrode of the organic light-emitting diode 214.

With the above structure, the switch thin-film transistor 208 is driven by a gate voltage applied to the gate lines 202, such that a data voltage applied to the data line 204 is transferred to the drive thin-film transistor 212. A voltage corresponding to the voltage difference between the common voltage transferred from the common power line 206 to the drive thin-film transistor 212 and the data voltage transferred via the switch thin-film transistor 208 is stored in the capacitor 210, and a current corresponding to the voltage stored in the capacitor 210 flows through the drive thin-film transistor 212 to the organic light-emitting diode 214. In this way, the organic light-emitting diode 214 emits light.

Optionally, the switch thin-film transistor 208 and the drive thin-film transistor 212 are both thin-film transistors having a PMOS structure doped with a p-type impurity. However, persons skilled in the art shall understand that the present disclosure is not limited thereto. Therefore, a thin-film transistor having an NMOS structure or a thin-film transistor having a CMOS structure may also serve as the switch thin-film transistor 208 or the drive thin-film transistor 212. The switch thin-film transistor 208 and the drive thin-film transistor 212 may be a polysilicon thin-film transistor, or an amorphous silicon thin-film transistor including an amorphous silicon layer. The capacitor 210 may be a ceramic capacitor.

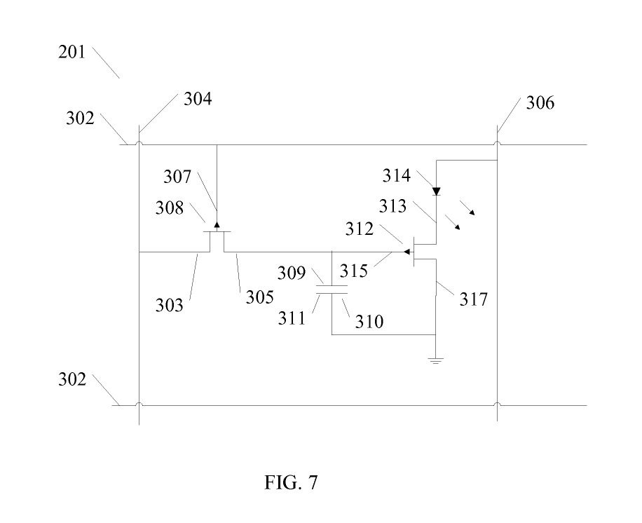

FIG. 7 is a schematic circuit diagram of a pixel unit of the pixel circuit of an organic light-emitting display according to a second embodiment of the present disclosure. Each of the plurality of pixel units 201 includes: a switch thin-film transistor 308, a drive thin-film transistor 312, a capacitor 310, and an organic light-emitting diode 314. Each of the plurality of pixel units 201 is defined in a region encircled by gate lines 302, a data line 304, and a common power line 306.

The organic light-emitting diode 314 includes a pixel electrode, an organic emitting layer formed on the pixel electrode, and a common electrode formed on the organic emitting layer. The pixel electrode serves as an anode of a hole injection electrode, and the common electrode serves as a cathode of an electron injection electrode. In a varied embodiment, according to a drive method of an organic light-emitting display, the pixel electrode may serve as the cathode, and the common electrode may serve as the anode. The hole and the electron are respectively injected into the organic emitting layer from the pixel electrode and the common electrode, and thus an exciton is formed. When the exciton transits from an excitation state to a ground state, light is emitted.

The switch thin-film transistor 308 includes: a switch semiconductor layer (not illustrated in the drawing), a switch gate electrode 307, a switch source electrode 303, and a switch drain electrode 305. The drive thin-film transistor 312 includes: a drive semiconductor layer (not illustrated in the drawing), a drive gate electrode 315, a drive source electrode 313, and a drive drain electrode 317.

The capacitor 310 includes a first sustain electrode 309 and a second sustain electrode 311, wherein an interlayer insulating layer is disposed between the first sustain electrode 309 and the second sustain electrode 311.

The switch thin-film transistor 308 serves as a switch for selecting a pixel for light emitting. The switch gate electrode 307 is connected to the gate line 302. The switch source electrode 303 is connected to the data line 304. The switch drain electrode 305 is disposed as being spaced apart from the switch source electrode 303 by a specific distance, and the switch drain electrode 305 is connected to the first sustain electrode 309.

The drive thin-film transistor 312 applies a drive power to the pixel electrode, such that the organic emitting layer of the organic light-emitting diode 314 of the selected pixel emits light. The drive gate electrode 315 is connected to the first sustain electrode. The drive drain electrode 317 and the second sustain electrode 311 are each grounded. The drive source electrode 313 is connected to the common electrode of the organic light-emitting diode 314. The pixel electrode of the organic light-emitting diode 314 is connected to the common power line 306.

With the above structure, the switch thin-film transistor 308 is driven by a gate voltage applied to the gate lines 302, such that a data voltage applied to the data line 304 is transferred to the drive thin-film transistor 312. A voltage corresponding to the voltage difference between the data voltage transferred via the switch thin-film transistor 308 and the ground voltage is stored in the capacitor 310, and a current corresponding to the voltage stored in the capacitor 310 flows through the drive thin-film transistor 312 to the organic light-emitting diode 314. In this way, the organic light-emitting diode 314 emits light.

Optionally, the switch thin-film transistor 308 and the drive thin-film transistor 312 are both thin-film transistors having a PMOS structure doped with a p-type impurity. However, persons skilled in the art shall understand that the present disclosure is not limited thereto. Therefore, a thin-film transistor having an NMOS structure or a thin-film transistor having a CMOS structure may also serve as the switch thin-film transistor 308 or the drive thin-film transistor 312. The switch thin-film transistor 308 and the drive thin-film transistor 312 may be a polysilicon thin-film transistor, or an amorphous silicon thin-film transistor including an amorphous silicon layer. The capacitor 310 may be a ceramic capacitor.

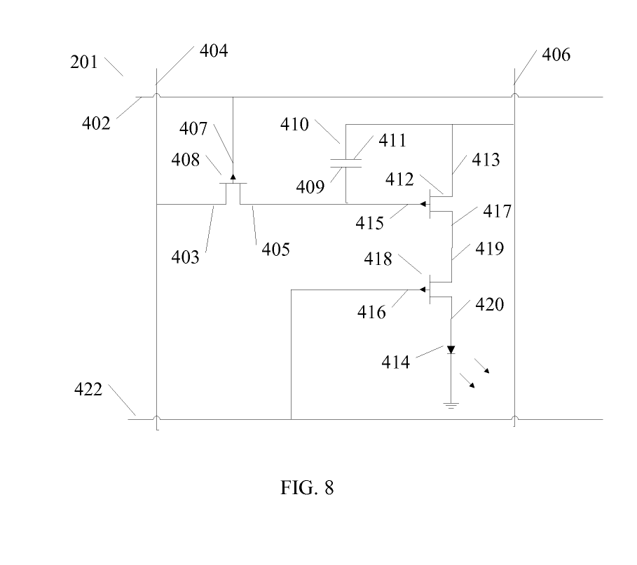

FIG. 8 is a schematic circuit diagram of a pixel unit of the pixel circuit of an organic light-emitting display according to a third embodiment of the present disclosure. Each of the plurality of pixel units 201 includes: a first switch thin-film transistor 408, a second switch thin-film transistor 418, a drive thin-film transistor 412, a capacitor 410, and an organic light-emitting diode 414. Each of the plurality of pixel units 201 is defined in a region encircled by a first gate line 402, a second gate line 422, a data line 404, and a common power line 406.

The organic light-emitting diode 414 includes a pixel electrode, an organic emitting layer formed on the pixel electrode, and a common electrode formed on the organic emitting layer. The pixel electrode serves as an anode of a hole injection electrode, and the common electrode serves as a cathode of an electron injection electrode. In a varied embodiment, according to a drive method of an organic light-emitting display, the pixel electrode may serve as the cathode, and the common electrode may serve as the anode. The hole and the electron are respectively injected into the organic emitting layer from the pixel electrode and the common electrode, and thus an exciton is formed. When the exciton transits from an excitation state to a ground state, light is emitted.

The first switch thin-film transistor 408 includes: a first switch semiconductor layer (not illustrated in the drawing), a first switch gate electrode 407, a first switch source electrode 403, and a first switch drain electrode 405. The second switch thin-film transistor 418 includes: a second switch semiconductor layer (not illustrated in the drawing), a second switch gate electrode 416, a second switch source electrode 419, and a second switch drain electrode 420. The drive thin-film transistor 412 includes: a drive semiconductor layer (not illustrated in the drawing), a drive gate electrode 415, a drive source electrode 413, and a drive drain electrode 417.

The capacitor 410 includes a first sustain electrode 409 and a second sustain electrode 411, wherein an interlayer insulating layer is disposed between the first sustain electrode 409 and the second sustain electrode 411.

The first switch thin-film transistor 408 serves as a switch for selecting a pixel for light emitting. The first switch gate electrode 407 is connected to the first gate line 402. The first switch source electrode 403 is connected to the data line 404. The first switch drain electrode 405 is disposed as being spaced apart from the first switch source electrode 403 by a specific distance, and the first switch drain electrode 405 is connected to the first sustain electrode 409.

The drive thin-film transistor 412 applies a drive power to the pixel electrode, such that the organic emitting layer of the organic light-emitting diode 414 of the selected pixel emits light. The drive gate electrode 415 is connected to the first sustain electrode. The drive source electrode 413 and the second sustain electrode 411 are each connected to the common power line 406. The drive drain electrode 417 is connected to the second switch source electrode 419 of the second switch thin-film transistor 418.

The second switch thin-film transistor 418 serves as a switch for protecting light emitting of the organic light-emitting diode 414. The second switch gate electrode 416 is connected to the second gate line 422. The second switch source electrode 419 is connected to the drive drain electrode 417. The second switch drain electrode 420 is connected to the pixel electrode of the organic light-emitting diode 414. The common electrode of the organic light-emitting diode 414 is grounded.

With the above structure, the switch thin-film transistor 408 is driven by a gate voltage applied to the first gate line 402, such that a data voltage applied to the data line 404 is transferred to the drive thin-film transistor 412. A voltage corresponding to the voltage difference between the data voltage transferred via the switch thin-film transistor 408 and the ground voltage is stored in the capacitor 410, and a current corresponding to the voltage stored in the capacitor 410 flows through the drive thin-film transistor 412 to the second switch thin-film transistor 418 and then to the organic light-emitting diode 414. In this way, the organic light-emitting diode 414 emits light.

Specifically, an input level of the first gate line 402 is reverse to that of the second gate line 422. When a low level is input to the first gate line 402, a high level is input to the second gate line 422. In this case, the first switch thin-film transistor 408 is turned on and enters a linear operating state. The second switch thin-film transistor 418 is cut off. A data signal is transferred via the first switch thin-film transistor 408 to the drive gate electrode 415 of the drive thin-film transistor 412, and the capacitor 410 starts to be charged. Since the second switch thin-film transistor 418 is cut off, the organic light-emitting diode 414 emits no light.

When a high level is input to the first gate line 402, a low level is input to the second gate line 422. In this case, the first switch thin-film transistor 408 is cut off. The second switch thin-film transistor 418 is turned on and enters a linear operating state. The voltage applied at two ends of the capacitor 410 remains unchanged, and the drive thin-film transistor 412 enters a saturation state. Further, since the second switch thin-film transistor 418 is turned on, a leakage current of the drive thin-film transistor 412 flows through the second switch thin-film transistor 418 to the organic light-emitting diode 414. In this way, the organic light-emitting diode 414 emits light.

Optionally, the first switch thin-film transistor 408, the second switch thin-film transistor 418, and the drive thin-film transistor 412 are all thin-film transistors having a PMOS structure doped with a p-type impurity. However, persons skilled in the art shall understand that the present disclosure is not limited thereto. Therefore, a thin-film transistor having an NMOS structure or a thin-film transistor having a CMOS structure may also serve as the first switch thin-film transistor 408, the second switch thin-film transistor 418 or the drive thin-film transistor 412. The first switch thin-film transistor 408, the second switch thin-film transistor 418 and the drive thin-film transistor 412 may be a polysilicon thin-film transistor, or an amorphous silicon thin-film transistor including an amorphous silicon layer. The capacitor 410 is a ceramic capacitor.

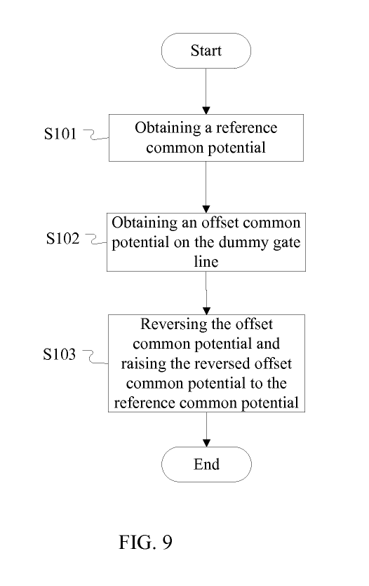

FIG. 9 is a flowchart of a compensation method of a pixel circuit of an organic light-emitting display according to the present disclosure. As shown in FIG. 9, the method includes the following steps:

Step S101: obtaining a reference common potential;

Step S102: obtaining an offset common potential on the dummy gate line; and

Step S103: reversing the offset common potential and raising the reversed offset common potential to the reference common potential.

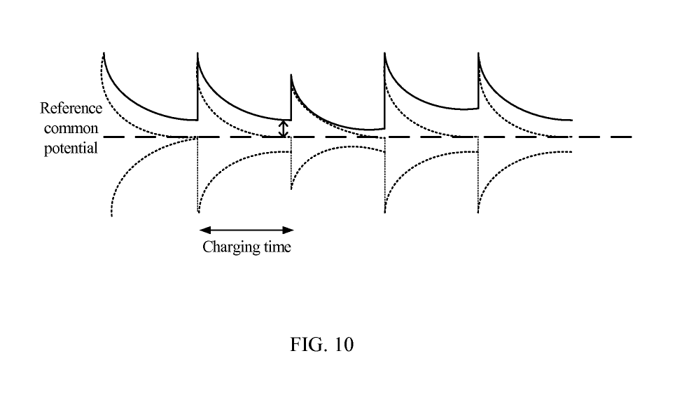

FIG. 10 is a schematic diagram illustrating common potential changes of the pixel circuit of an organic light-emitting display according to the present disclosure. The offset common potential obtained on the dummy gate line is reversed and then raised to the reference common potential, such that the organic light-emitting display emits light normally.

Detailed above are exemplary embodiments of the present disclosure. It shall be understood that the present disclosure is not limited to the above exemplary embodiments. On the contrary, the present disclosure is intended to cover various modifications and equivalent deployments within the spirit and scope of the appended claims.

What is claimed is:

1. A pixel circuit of a display, comprising:
a plurality of gate lines;
a plurality of data lines intersecting with and being insulated against the plurality of gate lines;
a plurality of common power lines intersecting with and being insulated against the plurality of gate lines;
a plurality of pixel units defined in regions encircled by the plurality of gate lines, the plurality of data lines, and the plurality of common power lines; and
a dummy gate line, extended in the same direction as the plurality of gate lines, intersecting with and being insulated against the plurality of data lines and the plurality of common power lines, wherein an offset common potential obtained on the dummy gate line is configured to make a common potential compensation for the pixel circuit.

2. The pixel circuit according to claim 1, wherein the dummy gate line is positioned on one side of the plurality of gate lines.

3. The pixel circuit according to claim 1, further comprising:
a plurality of dummy pixel units defined in regions encircled by the dummy gate line, the plurality of data lines, and the plurality of common power lines.

4. The pixel circuit according to claim 3, wherein the plurality of dummy pixel units have the same circuit structure as the plurality of pixel units.

5. The pixel circuit according to claim 4, wherein each of the plurality of pixel units comprises:
a switch thin-film transistor, having a switch gate electrode, a switch source electrode, and a switch drain electrode;
a drive thin-film transistor, having a drive gate electrode, a drive source electrode, and a drive drain electrode;
a capacitor, having a first sustain electrode and a second sustain electrode; and
a light-emitting diode;
wherein the switch gate electrode of the switch thin-film transistor is connected to the gate line, the switch source electrode of the switch thin-film transistor is connected to the data line, the switch drain electrode of the switch thin-film transistor is connected to the first sustain electrode and the drive gate electrode of the drive thin-film transistor, the drive source electrode of the drive thin-film transistor and the second sustain electrode of the capacitor are respectively connected to the common power line, the drive drain electrode of the drive thin-film transistor is connected to a positive pole of the light-emitting diode, and a negative pole of the light-emitting diode is grounded.

6. The pixel circuit according to claim 5, wherein the switch thin-film transistor and the drive thin-film transistor employ one of the following structures:
a p-channel metal oxide semiconductor (PMOS) structure;
an n-channel metal oxide semiconductor (NMOS) structure; and
a complementary metal oxide semiconductor (CMOS) structure.

7. The pixel circuit according to claim 6, wherein the switch thin-film transistor and the drive thin-film transistor employ one of the following transistors:
a polysilicon thin-film transistor; and
an amorphous silicon thin-film transistor.

8. The pixel circuit according to claim 5, wherein the capacitor is a ceramic capacitor.

9. The pixel circuit according to claim 5, wherein the light-emitting diode is an organic light-emitting diode.

10. The pixel circuit according to claim 4, wherein each of the plurality of pixel units comprises:
a switch thin-film transistor, having a switch gate electrode, a switch source electrode, and a switch drain electrode;
a drive thin-film transistor, having a drive gate electrode, a drive source electrode, and a drive drain electrode;
a capacitor, having a first sustain electrode and a second sustain electrode; and
a light-emitting diode;
wherein the switch gate electrode of the switch thin-film transistor is connected to the gate line, the switch source electrode of the switch thin-film transistor is connected to the data line, the switch drain electrode of the switch thin-film transistor is connected to the first sustain electrode and the drive gate electrode of the drive thin-film transistor, the drive drain electrode of the drive thin-film transistor and the second sustain electrode of the capacitor are respectively grounded, the drive source electrode of the drive thin-film transistor is connected to a negative pole of the light-emitting diode, and a positive pole of the light-emitting diode is connected to the common power line.

11. The pixel circuit according to claim 10, wherein the switch thin-film transistor and the drive thin-film transistor employ one of the following structures:
a p-channel metal oxide semiconductor (PMOS) structure;
an n-channel metal oxide semiconductor (NMOS) structure; and
a complementary metal oxide semiconductor (CMOS) structure.

12. The pixel circuit according to claim 11, wherein the switch thin-film transistor and the drive thin-film transistor employ one of the following transistors:
a polysilicon thin-film transistor; and
an amorphous silicon thin-film transistor.

13. The pixel circuit according to claim 10, wherein the capacitor is a ceramic capacitor.

14. The pixel circuit according to claim 10, wherein the light-emitting diode is an organic light-emitting diode.

15. The pixel circuit according to claim 4, wherein each of the plurality of pixel units comprises:
a first switch thin-film transistor, having a first switch gate electrode, a first switch source electrode, and a first switch drain electrode;
a second switch thin-film transistor, having a second switch gate electrode, a second switch source electrode, and a second switch drain electrode;
a drive thin-film transistor, having a drive gate electrode, a drive source electrode, and a drive drain electrode;
a capacitor, having a first sustain electrode and a second sustain electrode; and
a light-emitting diode;
wherein the first switch gate electrode of the first switch thin-film transistor is connected to a first gate line, the first switch source electrode of the first switch thin-film transistor is connected to the data line, the first switch drain electrode of the first switch thin-film transistor is connected to the first sustain electrode of the capacitor and the drive gate electrode of the drive thin-film transistor, the drive source electrode of the drive thin-film transistor and the second sustain electrode are respectively connected to the common power line, the drive drain electrode of the drive thin-film transistor is connected to the second switch source electrode of the second switch thin-film transistor, the second switch gate electrode of the second switch thin-film transistor is connected to a second gate line, the second switch drain electrode of the second switch thin-film transistor is connected to a positive pole of the light-emitting diode, and a negative pole of the light-emitting diode is grounded.

16. The pixel circuit according to claim 15, wherein an input level of the first gate line is reverse to that of the second gate line.

17. The pixel circuit according to claim 15, wherein the first switch thin-film transistor, the second switch thin-film transistor, and the drive thin-film transistor employ one of the following structures:
a p-channel metal oxide semiconductor (PMOS) structure;
an n-channel metal oxide semiconductor (NMOS) structure; and
a complementary metal oxide semiconductor (CMOS) structure.

18. The pixel circuit according to claim 17, wherein the first switch thin-film transistor, the second switch thin-film transistor, and the drive thin-film transistor employ one of the following transistors:
a polysilicon thin-film transistor; and
an amorphous silicon thin-film transistor.

19. The pixel circuit according to claim 15, wherein the capacitor is a ceramic capacitor, and the light-emitting diode is an organic light-emitting diode.

20. A common potential compensation method based on the pixel circuit according to claim 1, comprising:
obtaining a reference common potential;
obtaining an offset common potential on the dummy gate line; and
reversing the offset common potential and raising the reversed offset common potential to the reference common potential.
